(19) United States
(12) Patent Application Publication
(10) Pub. No.: US 2019/0363304 A1
(43) Pub. Date: Nov. 28, 2019

(54) EL DEVICE PRODUCING METHOD AND EL DEVICE PRODUCING DEVICE

(71) Applicant: Sharp Kabushiki Kaisha, Sakai City, Osaka (JP)

(72) Inventors: Tetsunori TANAKA, Sakai City (JP); Katsuyuki SUGA, Sakai City (JP); Yuki YASUDA, Sakai City (JP)

(21) Appl. No.: 16/067,617

(22) PCT Filed: Mar. 30, 2017
(86) PCT No.: PCT/JP2017/013356

§ 371 Date: Jul. 2, 2018

(51) Int. Cl. H01L 51/56; H01L 51/52; H01L 27/32

(52) U.S. Cl. CPC H01L 51/56; H01L 27/32; H01L 51/5253

(57) ABSTRACT

A method of producing an EL device includes layering a resin layer, a barrier layer and a protective film on a mother glass substrate, the layering including forming, along an end face of the mother glass substrate, an adhesive strengthening layer to strengthen adhesive force between the barrier layer and the protective film.

### TECHNICAL FIELD

The disclosure relates to a method of producing an Electro Luminescence (EL) device, and an EL device producing device. The method includes irradiating with a laser beam a back surface of a mother glass substrate on which a resin layer, an inorganic sealing film and a protective film are layered, and separating the mother glass substrate from the resin layer by inserting a knife along an interface between the mother glass substrate and the resin layer.

### BACKGROUND ART

As a method of producing a thin film device such as an EL device, there is known a producing method including layering a separation layer and a thin film device on a first base material, bonding a second base material onto the thin film device, separating the first base material from the thin film device side by causing a separation phenomenon at an interface between the separation layer and the first base material, and transferring the thin film device to the second base material side (PTL 1).

In this producing method, portions having partially different adhesive force at the interface between the separation layer and the first base material are provided to form a separation film, and these portions having partially different adhesive force are formed by surface treatment of the first base material.

### CITATION LIST

### Patent Literature

PTL 1: JP 2005-183615 (published Jul. 7, 2005)

### SUMMARY

### Technical Problem

Recently, there is an increasing demand for a display panel that can be curved, for example as a display panel on which a flexible EL device is formed. When such a display panel is produced, a layered body including a resin layer, an EL layer, an inorganic sealing film and a protective film is formed on a mother glass substrate, and after a back surface of the mother glass substrate is irradiated with a laser beam, a knife is inserted along an interface between the mother glass substrate and the resin layer to separate the mother glass substrate from the resin layer, and a flexible lower face film is bonded to the resin layer.

However, there is a problem in adhesive force between the resin layer and the mother glass substrate that is difficult to decrease in a peripheral region of the resin layer even after laser beam irradiation. Accordingly, when the protective film has weak adhesive force to be bonded onto the inorganic sealing film prior to laser beam irradiation, the knife inserted to separate the mother glass substrate slips and cuts into an interface between the protective film and the inorganic sealing film rather than the interface between the resin layer and the mother glass substrate, and separation failure may occur. This is assumed to be caused by adhesive force between the protective film and the inorganic sealing film that is less than or equal to adhesive force between the resin layer and the mother glass substrate in the peripheral region.

Although occurrence of separation failure can be suppressed to some degree by increasing intensity of a laser beam used at the time of laser beam irradiation and decreasing adhesive force between the resin layer and the mother glass substrate in the peripheral region, it is not desirable to increase the intensity of the laser beam because the increase in the intensity of the laser beam is associated with an increase in ash.

In addition, since the protective film on the inorganic sealing film is expected to be separated after a lighting test of the display panel, it is not possible to use the protective film having strong adhesive force to make adhesive force between the protective film and the inorganic sealing film equal to adhesive force between the resin layer and the mother glass substrate in the peripheral region.

### Solution to Problem

A method of producing an EL device according to an aspect of the disclosure includes layering a resin layer, an inorganic sealing film and a protective film on a mother glass substrate; irradiating with a laser beam from a side opposite to the resin layer of the mother glass substrate; separating the mother glass substrate from the resin layer by inserting a knife along an interface between the mother glass substrate and the resin layer; and bonding a lower face film to the resin layer from which the mother glass substrate is separated, and in the method, the layering includes forming, along an end face of the mother glass substrate, an adhesive strengthening layer to strengthen adhesive force between the inorganic sealing film and the protective film.

### Advantageous Effects of Disclosure

According to an aspect of the disclosure, it is possible to provide a method of producing an EL device and an EL device producing device capable of satisfactorily separating a mother glass substrate.

### BRIEF DESCRIPTION OF DRAWINGS

FIG. 1 is a plan view of a mother glass substrate according to a first embodiment.

FIG. 2A is a cross-sectional view taken along a plane AA illustrated in FIG. 1, and

FIG. 2B is a cross-sectional view taken along the plane AA in a state in which the mother glass substrate is separated and a lower face film is bonded.

FIG. 3 is a cross-sectional view taken along a plane BB illustrated in FIG. 1.

FIG. 4A is a flowchart illustrating a method of producing an EL device according to the first embodiment, and FIG. 4B is a flowchart illustrating a primary part of a method of producing a flexible EL device according to the first embodiment.

FIG. 5A is a cross-sectional view taken along a plane CC illustrated in FIG. 1, and FIG. 5B is a cross-sectional view taken along a plane FF illustrated in FIG. 1.

FIG. 6A is a cross-sectional view of an end portion region of the mother glass substrate, and FIG. 6B is a cross-sectional view taken along a direction orthogonal to a surface of the mother glass substrate.

FIG. 7 is a cross-sectional view illustrating a laser beam irradiation step of the method of producing an EL device.

FIG. 8 is a cross-sectional view illustrating a separation step of the method of producing an EL device.

FIG. 9 is a cross-sectional view illustrating a bonding step of the method of producing an EL device.

FIG. 10 is a cross-sectional view illustrating a separation step according to a comparative example.

FIG. 11A is a cross-sectional view of an end portion region of a mother glass substrate according to a second embodiment, and FIG. 11B is a cross-sectional view taken along a direction orthogonal to a surface of the mother glass substrate.

FIG. 12A is a cross-sectional view of an end portion region of a mother glass substrate according to a third embodiment, and FIG. 12B is a cross-sectional view taken along a direction orthogonal to a surface of the mother glass substrate.

FIG. 13A is a cross-sectional view of an end portion region of a mother glass substrate according to a fourth embodiment, and FIG. 13B is a cross-sectional view taken along a direction orthogonal to a surface of the mother glass substrate.

### DESCRIPTION OF EMBODIMENTS

### First Embodiment

### Mother Glass Substrate 50

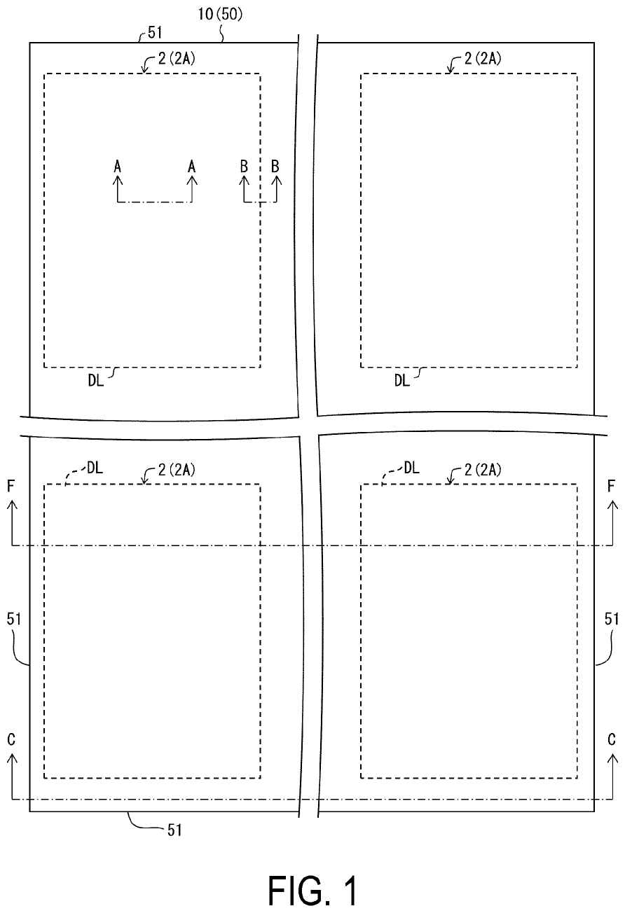

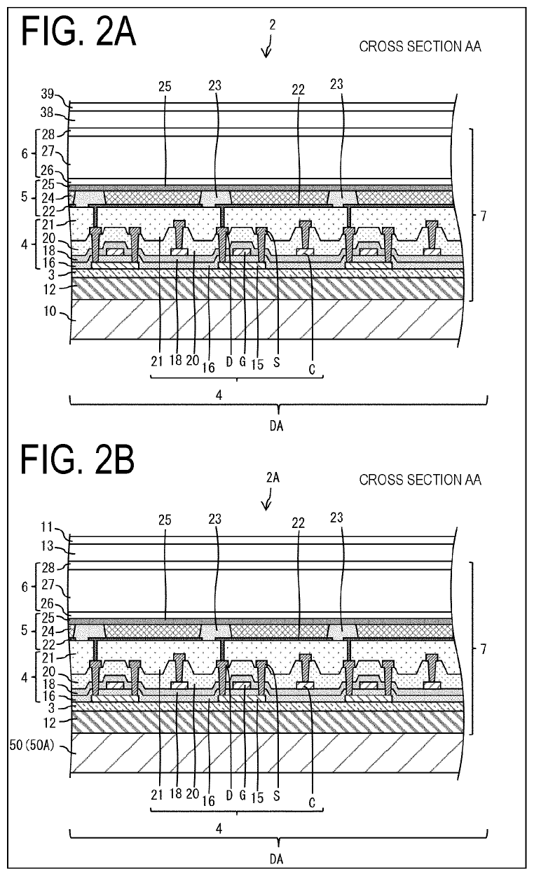

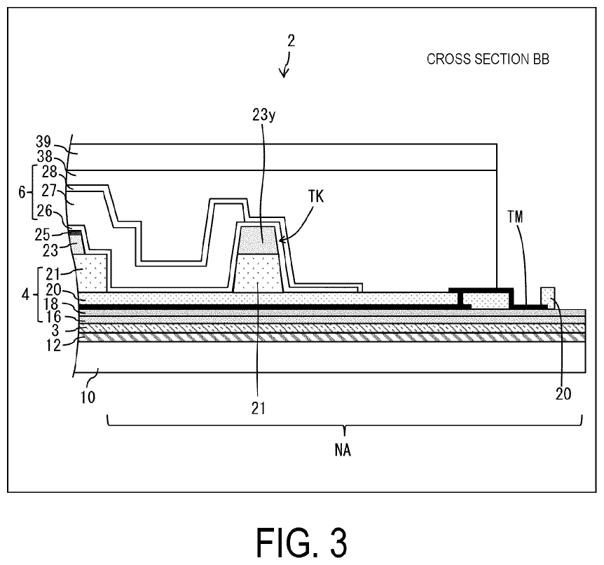

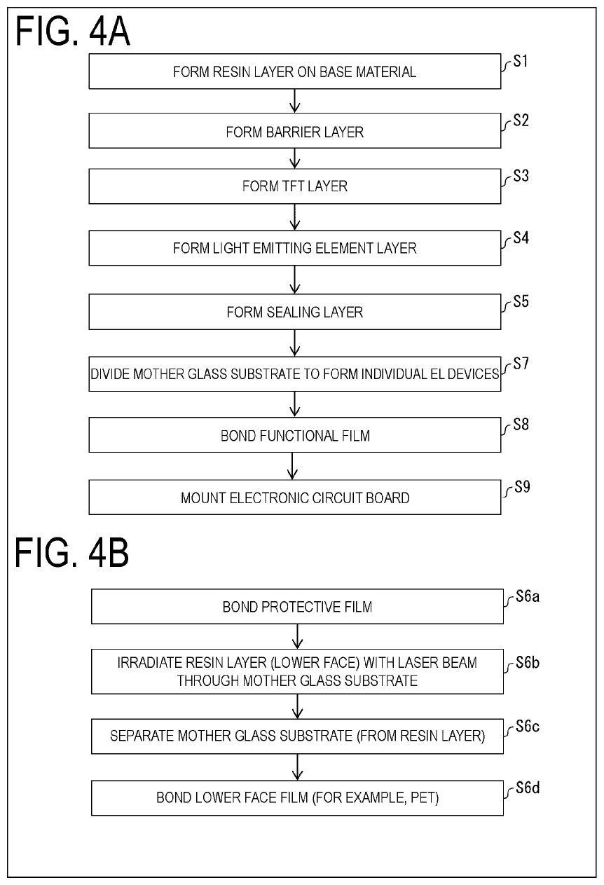

FIG. 1 is a plan view of a mother glass substrate 50 (mother base material 10) according to a first embodiment. FIG. 2A is a cross-sectional view taken along a plane AA illustrated in FIG. 1, and FIG. 2B is a cross-sectional view taken along the plane AA in a state in which the mother glass substrate 50 is separated and a lower face film 50A is bonded. FIG. 3 is a cross-sectional view taken along a plane BB illustrated in FIG. 1. FIG. 4A is a flowchart illustrating a method of producing an EL device according to the first embodiment, and FIG. 4B is a flowchart illustrating a primary part of a method of producing a flexible EL device according to the first embodiment.

First, a method of producing an EL device having rigidity will be described.

As illustrated in FIG. 1, FIG. 2A and FIG. 4A, first, a resin layer 12 is formed on the mother base material 10 (step S1). Then, a barrier layer 3 is formed (step S2). Then, a Thin Film Transistor (TFT) layer 4 including a gate insulating film 16, passivation films 18 and 20 and an organic interlayer film 21 is formed (step S3). Then, a light emitting element layer (for example, an Organic Light Emitting Diode (OLED) element layer) 5 is formed (step S4). Then, a sealing layer 6 including inorganic sealing films 26 and 28 and an organic sealing film 27 is formed to obtain a layered body 7 (step SS). Then, the layered body 7 together with the mother base material 10 is divided along a dividing line DL (FIG. 1) to form a plurality of individual EL devices 2 (step S7). Then, a functional film 39 is bonded via an adhesive layer 38 (step S8). Then, an electronic circuit board is mounted on an end portion of the TFT layer 4 (step S9). Note that each of the above steps is performed by an EL device producing device.

Next, a method of producing a flexible EL device 2A will be described.

When the flexible EL device 2A is produced, as illustrated in FIG. 1, FIG. 2B and FIG. 4B, for example, the layered body 7 (the resin layer 12, the barrier layer 3, the TFT layer 4, the light emitting element layer 6 and the sealing layer 6) is formed in advance on the mother glass substrate 50, and a protective film 11 is bonded onto the layered body 7 via an adhesive layer 13 (step S6a). Then, a lower face of the resin layer 12 is irradiated with a laser beam through the mother glass substrate 50 (step S6b). Here, the lower face of the resin layer 12 (an interface between the resin layer 12 and the mother glass substrate 50) is altered by ablation, and bonding force between the resin layer 12 and the mother glass substrate 50 decreases. Then, the mother glass substrate 50 is separated from the resin layer 12 (step S6c). Then, a lower face film 50A including PolyEthylene Terephthalate (PET) or the like is bonded to the lower face of the resin layer 12 via the adhesive layer 13 (step S6d). Subsequently, the method proceeds to step S7.

Examples of a material for the resin layer 12 include polyimide, epoxy and polyamide. An example of a material for the lower face film 50A includes PolyEthylene Terephthalate (PET).

The barrier layer 3 prevents moisture and impurities from reaching the TFT layer 4 and the light emitting element layer 5 when the EL device is in use. For example, the barrier layer 3 can include a silicon oxide film, a silicon nitride film or a silicon oxynitride film formed by CVD (Chemical Vapor Deposition), or a layered film of these films.

The TFT layer 4 includes a semiconductor film 15, a gate insulating film 16 formed above the semiconductor film 15, a gate electrode G formed above the gate insulating film 16, the passivation films 18 and 20 formed above the gate electrode G, a capacitor electrode C and a terminal TM (FIG. 3) formed above the passivation film 18, a source line S and a drain line D formed above the passivation film 20, and an organic interlayer film (flattening film) 21 formed above the source line S and the drain line D. A Thin Film Transistor (TFT) is constituted to include the semiconductor film 15, the gate insulating film 16 and the gate electrode G. In a non-active region NA of the TFT layer 4, a plurality of the terminals TM used for connection with the electronic circuit board is formed (FIG. 3).

The semiconductor film 15 includes, for example, low-temperature polysilicon (Low-Temperature Polycrystalline Silicon (LTPS)) or an oxide semiconductor. The gate insulating film 16 can include, for example, a silicon oxide (SiOx) film or a silicon nitride (SiNx) film formed by CVD, or a layered film of these films. The gate electrode G, the source electrode S, the drain electrode D and the terminal TM each include, for example, a monolayer film or a layered film of metal including at least one of aluminum (Al), tungsten (W), molybdenum (Mo), tantalum (Ta), chromium (Cr), titanium (Ti) and copper (Cu). Note that in FIG. 2, although the TFT using the semiconductor film 15 as a channel is illustrated as a top gate structure, the TFT may include a bottom gate structure (for example, when the channel of the TFT is an oxide semiconductor).

The gate insulating film 16 and the passivation films 18 and 20 can each include, for example, a silicon oxide (SiOx) film or a silicon nitride (SiNx) film formed by CVD, or a layered film of these films. The organic interlayer film 21 can include, for example, a photosensitive organic material that can be applied, such as polyimide and acrylic.

The light emitting element layer 5 (for example, the organic light emitting diode layer) includes a first electrode 22 (for example, an anode electrode) formed above the organic interlayer film 21, an organic insulating film 23 covering an edge of the first electrode 22, an Electro Luminescence (EL) layer 24 formed above the first electrode 22 and a second electrode 25 formed above the EL layer 24, and the first electrode 22, the EL layer 24 and the second electrode 25 constitute a light emitting element (for example, an organic light emitting diode). The organic insulating film 23 in an active region DA functions as a bank (pixel partition) defining a subpixel region.

The organic insulating film 23 can include, for example, a photosensitive organic material that can be applied, such as polyimide and acrylic. For example, the organic insulating film 23 can be applied to the active region DA and the non-active region NA by an ink-jet method.

The non-active region NA is provided with a bank-shaped convex body TK surrounding the active region DA. The convex body TK defines an edge of the organic sealing film 27 (for example, a film formed by an ink-jet method). The convex body TK is constituted to include, for example, at least one of the organic interlayer film 21 and the organic insulating film 23.

The EL layer 24 is formed by vapor deposition or an ink-jet method in a region (subpixel region) surrounded by the organic insulating film 23. When the light emitting element layer 5 includes an Organic Light Emitting Diode (OLED) layer, the EL layer 24 is constituted by, for example, layering a hole injecting layer, a hole transport layer, a light emitting layer, an electron transport layer and an electron injecting layer in this order from the lower layer side. Note that one or more of the EL layers 24 can also be a shared layer (shared by a plurality of pixels).

The first electrode (positive electrode) 22 includes a layered body of, for example, Indium Tin Oxide (ITO) and an alloy including Ag, and has optical reflectivity. The second electrode (for example, a cathode electrode) 25 is a shared electrode, and can include a transparent metal such as Indium Tin Oxide (ITO) and Indium Zinc Oxide (IZO).

When the light emitting element layer 5 includes an OLED layer, holes and electrons are recombined in the EL layer 24 by a drive current between the first electrode 22 and the second electrode 25, and resulting excitons fall into a ground state, and as a result, light is emitted.

The light emitting element layer 5 is not limited to the light emitting element layer including an OLED element, and may include an inorganic light emitting diode or a quantum dot light emitting diode.

The sealing layer 6 covers the light emitting element layer 5 and prevents penetration of foreign matter such as water and oxygen into the light emitting element layer 5. The sealing layer 6 includes an inorganic sealing film 26 covering the organic insulating film 23 and the second electrode 25, an organic sealing film 27 formed above the inorganic sealing film 26 and functioning as a buffer film, and an inorganic sealing film 28 covering the inorganic sealing film 26 and the organic sealing film 27.

Each of the inorganic sealing film 26 and the inorganic sealing film 28 can include, for example, a silicon oxide film, a silicon nitride film or a silicon oxynitride film formed by CVC using a mask, or a layered film of these films. The organic sealing film 27 include a transparent organic insulating film thicker than the inorganic sealing film 26 and the inorganic sealing film 28, and can include a photosensitive organic material that can be applied, such as polyimide and acrylic. For example, ink including such an organic material is ink-jet applied onto the inorganic sealing film 26, and subsequently cured by UltraViolet (UV) irradiation.

The functional film 39 has, for example, an optical compensation function, a touch sensor function, a protection function and the like. When a layer having one or more of these functions is layered above the light emitting element layer 5, the functional film 39 can also be thinned or removed. The electronic circuit board includes, for example, an IC chip or a Flexible Printed Circuit (FPC) mounted on the plurality of terminals TM.

### Laser Beam Irradiation Step and Separation Step

The laser beam irradiation step (step S6b) and the separation step (step S6c) for producing the flexible EL device according to the first embodiment will be described below in detail.

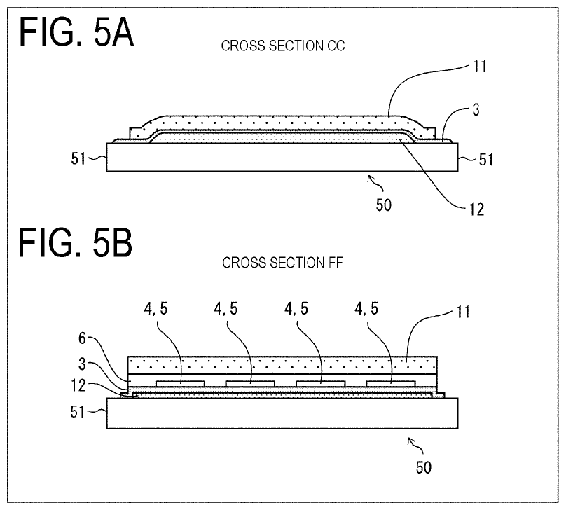

FIG. 5A is a cross-sectional view taken along a plane CC illustrated in FIG. 1, and corresponds to FIG. 2B illustrating the flexible EL device. FIG. 5B is a cross-sectional view taken along a plane FF illustrated in FIG. 1.

As illustrated in FIG. 5A and FIG. 5B, on the plane CC and the plane FF, the barrier layer 3 illustrated in FIG. 2B is layered on the resin layer 12 to cover an entire surface of the resin layer 12. Then, as illustrated in FIG. 5B, on the plane FF, the TFT layer 4 and the light emitting element layer 5 are formed on the barrier layer 3. Then, the sealing layer 6 is layered to cover the TFT layer 4 and the light emitting element layer 5, and the protective film 11 is formed on the sealing layer 6. On the plane CC, the protective film 11 is layered on the barrier layer 3 as illustrated in FIG. 5A.

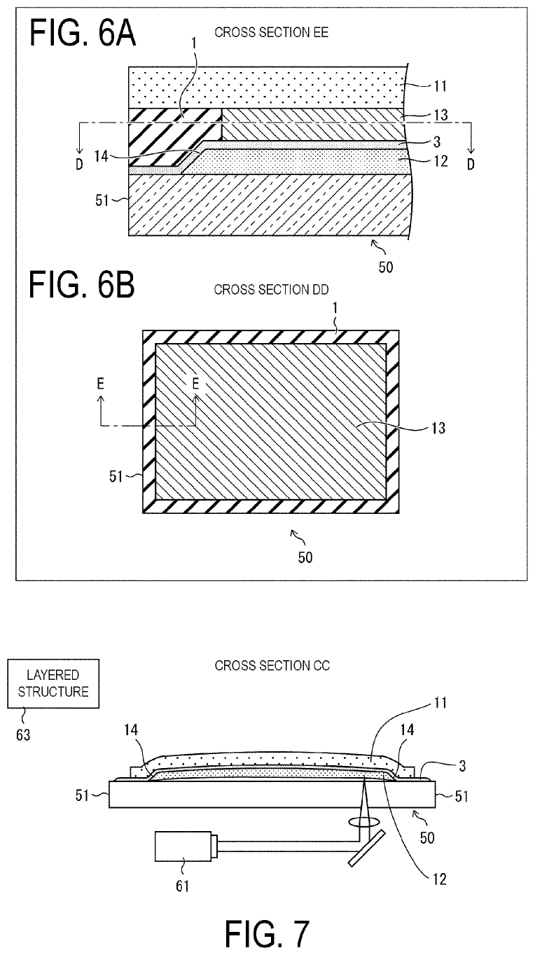

FIG. 6A is a cross-sectional view of an end portion region of the mother glass substrate 50, and FIG. 6B is a cross-sectional view taken along a direction orthogonal to a surface of the mother glass substrate 50. FIG. 6B corresponds to a cross section taken along a plane DD illustrated in FIG. 6A, and FIG. 6A corresponds to a cross section taken along a plane EE illustrated in FIG. 6B.

The resin layer 12 includes an inclined surface 14 having a film thickness decreasing toward an end face 51 of the mother glass substrate 50. The barrier layer 3 is formed along a surface of the resin layer 12, the inclined surface 14 and a surface region of the mother glass substrate 50 between the inclined surface 14 and the end face 51. As illustrated in FIG. 5A and FIG. 5B, the barrier layer 3 is formed to cover the entire surface of the resin layer 12. The protective film 11 is formed on the barrier layer 3 via the adhesive layer 13. For example, an adhesive used for bonding a polarizing plate is used for the adhesive layer 13.

An adhesive strengthening layer 1 is formed along the end face 51 of the mother glass substrate 50 to strengthen adhesive force between the barrier layer 3 and the protective film 11. In the example illustrated in FIG. 6, the adhesive strengthening layer 1 is formed to reach the end face 51 of the mother glass substrate 50. Then, the adhesive strengthening layer 1 is formed along four sides of the mother glass substrate 50. Thus, the adhesive strengthening layer 1 is formed only at a peripheral portion of the inorganic sealing film 28. Accordingly, the protective film 11 having adhesive force strengthened only at the peripheral portion is bonded to the inorganic sealing film 28.

The configuration of the adhesive strengthening layer 1 and the adhesive layer 13 can be realized by using a special protective film having different adhesive force in a plane parallel to the surface of the mother glass substrate 50.

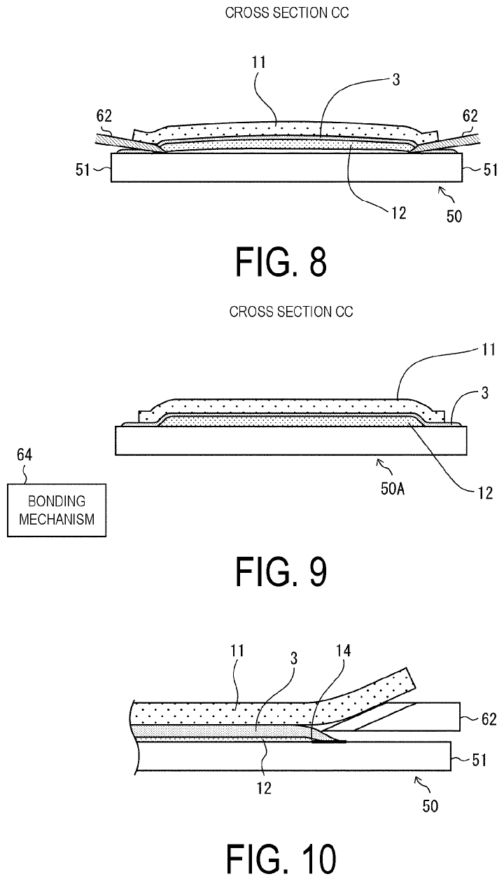

FIG. 7 is a cross-sectional view illustrating a laser beam irradiation step (Laxer Lift Off (LLO) step) of the method of producing the EL device 2A. FIG. 8 is a cross-sectional view illustrating a separation step of the method of producing the EL device 2A. FIG. 9 is a cross-sectional view illustrating a bonding step of the method of producing the EL device 2A.

After the layered body 7 is layered on the mother glass substrate 50 by a layering mechanism 63 and the protective film 11 is bonded via the adhesive layer 13, the lower face of the resin layer 12 is irradiated with a laser beam through the mother glass substrate 50 by a laser beam irradiation mechanism 61 as described above with reference to FIG. 4B. Then, a knife 62 (separation mechanism) is inserted along an interface between the mother glass substrate 50 and the resin layer 12 to separate the mother glass substrate 50 from the resin layer 12. Next, the lower face film 50A is bonded to the resin layer 12 by a bonding mechanism 64.

When the laser beam irradiation mechanism 61 irradiates with a laser beam, adhesive force between a center portion of the resin layer 12 and a center portion of the mother glass substrate 50 decreases. On the other hand, adhesive force between the resin layer 12 and the mother glass substrate 50 is difficult to decrease in a region corresponding to the inclined surface 14 where the film thickness of the resin layer 12 abruptly changes. In the first embodiment, adhesive force between the barrier layer 3 and the protective film 11 is strengthened by the adhesive strengthening layer 1. Accordingly, in the region corresponding to the inclined surface 14, adhesive force between the protective film 11 and the barrier layer 3 is much greater than adhesive force between the mother glass substrate 50 and the resin layer 12. Therefore, the knife 62 can be inserted along the interface between the mother glass substrate 50 and the resin layer 12 to satisfactorily separate the mother glass substrate 50 from the resin layer 12.

### Comparative Example

FIG. 10 is a cross-sectional view illustrating a separation step according to a comparative example. As described above, even when laser beam irradiation is carried out, adhesive force between a mother glass substrate 50 and a resin layer 12 is difficult to decrease in a region corresponding to an inclined surface 14 where a film thickness of a resin layer 12 abruptly changes. Accordingly, in the region corresponding to the inclined surface 14, adhesive force between a protective film 11 and a barrier layer 3 becomes less than or equal to adhesive force between the mother glass substrate 50 and the resin layer 12. In this case, a knife 62 inserted to separate the mother glass substrate 50 slips and cuts into an interface between the protective film 11 and the barrier layer 3 rather than an interface between the resin layer 12 and the mother glass substrate 50, and separation failure may occur to cause separation of the protective film 11 rather than separation of the mother glass substrate 50. Since the protective film 11 on the barrier layer 3 is expected to be separated after a lighting test of an EL device 2A, it is not possible to use the protective film 11 having a strong adhesive force to make adhesive force between the protective film 11 and the barrier layer 3 greater than or equal to adhesive force between the resin layer 12 and the mother glass substrate 50 in the region corresponding to the inclined surface 14.

In contrast, in the first embodiment, the adhesive strengthening layer 1 is formed along the end face 51 of the mother glass substrate 50 to strengthen adhesive force between the barrier layer 3 and the protective film 11. Accordingly, adhesive force between the barrier layer 3 and the protective film 11 is strengthened along the end face 51 of the mother glass substrate 50. Accordingly, in the region corresponding to the inclined surface 14, adhesive force between the protective film 11 and the barrier layer 3 becomes much greater than adhesive force between the mother glass substrate 50 and the resin layer 12. Therefore, the knife 62 is prevented from entering the interface between the protective film 11 and the barrier layer 3, and occurrence of the separation failure can be suppressed.

Adhesive force between the protective film 11 and the barrier layer 3 is from 0.01 to 0.05 N (Newtons)/25 mm (millimeters) in the comparative example, but the adhesive strength is strengthened about 100 times by forming the adhesive strengthening layer 1. The adhesive force between the protective film 11 and the barrier layer 3 is preferably 0.1 N/25 mm or greater. Then, the adhesive force between the protective film 11 and the barrier layer 3 is preferably about 2 to 10 times or more the adhesive force between the mother glass substrate 50 and the resin layer 12.

In addition, according to the first embodiment, since intensity of the laser beam used in the laser beam irradiation step can be lowered to the minimum level necessary, an effect of suppressing a decrease in yield due to ash can also be anticipated.

Note that since the region where the adhesive force is strengthened by the adhesive strengthening layer 1 is cut off at the time of dividing the mother glass substrate to form individual EL devices (step S7), the region does not impact processes in the steps after the formation of individual EL devices.

Although the above-described embodiment describes the example in which the adhesive strengthening layer 1 is formed along the four sides of the mother glass substrate 50, the disclosure is not limited to this example. The adhesive strengthening layer 1 may be formed along a side where the knife 62 is inserted for separation, and may be formed along at least one side.

### Second Embodiment

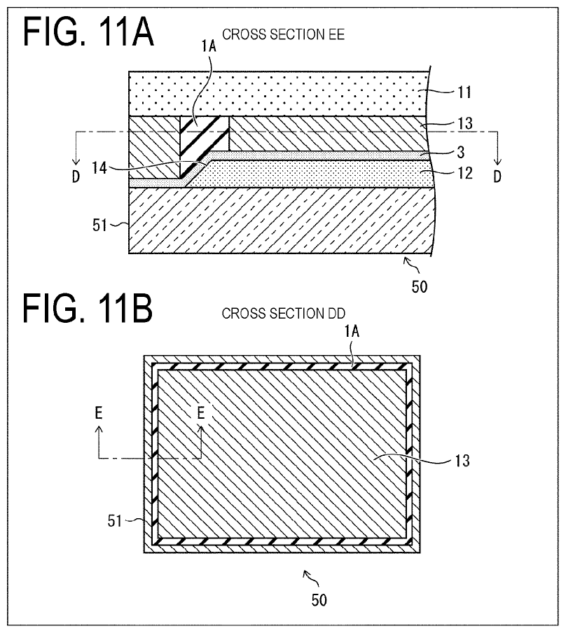

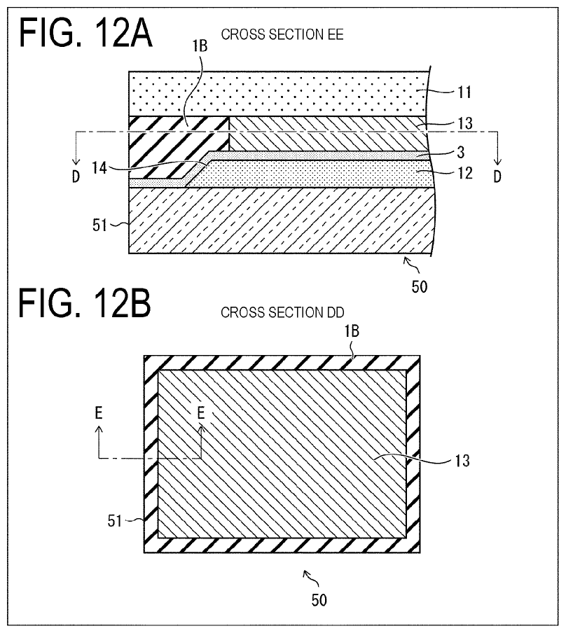

FIG. 11A is a cross-sectional view of an end portion region of a mother glass substrate 50 according to a second embodiment, and FIG. 11B is a cross-sectional view taken along a direction orthogonal to a surface of the mother glass substrate 50. The same reference signs are given to the same constituent elements as the constituent elements described in the first embodiment. Detailed description of these constituent elements will not be repeated.

The adhesive strengthening layer 1 according to the first embodiment is formed to reach the end face 51 of the mother glass substrate 50, whereas an adhesive strengthening layer 1A according to the second embodiment is formed only in a location corresponding to an end portion of a resin layer 12.

As illustrated in FIG. 11, the adhesive strengthening layer 1A is formed in a region along a periphery of the mother glass substrate 50 corresponding to a location beyond an upper end from a lower end of an inclined surface 14 of the resin layer 12. The adhesive strengthening layer 1A may be formed to cover a lower side of the inclined surface 14.

As a result, since the adhesive strengthening layer 1A is not formed in a region outside of the resin layer 12, adhesive force between a protective film 11 and the mother glass substrate 50 is not strengthened, and remains weak. Therefore, in addition to the effect of the first embodiment, the second embodiment exhibits an effect of easy insertion of a knife 62 for separation of the mother glass substrate 50.

### Third Embodiment

FIG. 12A is a cross-sectional view of an end portion region of a mother glass substrate 50 according to a third embodiment, and FIG. 12B is a cross-sectional view taken along a direction orthogonal to a surface of the mother glass substrate 50. The same reference signs are given to the same constituent elements as the constituent elements described in the first embodiment. Detailed description of these constituent elements will not be repeated.

In the third embodiment, a UV-curing resin or a thermosetting resin is used for an adhesive layer 13 of a protective film 11, and only a region along a periphery of the mother glass substrate 50 is irradiated with UV or heated to cure the UV-curing resin or the thermosetting resin and form an adhesive strengthening layer 1B.

Thus, since the adhesive strengthening layer 1B is formed by irradiating the adhesive layer 13 with UV or by heating the adhesive layer 13, it becomes unnecessary to use a special protective film having different adhesive force in a plane as in the first embodiment. Accordingly, in addition to the effect of the first embodiment, material cost can be reduced.

### Fourth Embodiment

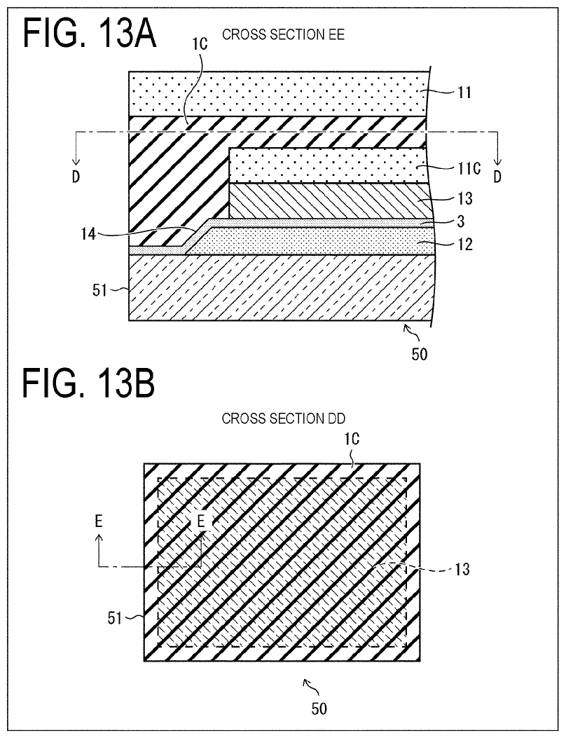

FIG. 13A is a cross-sectional view of an end portion region of a mother glass substrate 50 according to a fourth embodiment, and FIG. 13B is a cross-sectional view taken along a direction orthogonal to a surface of the mother glass substrate 50. The same reference signs are given to the same constituent elements as the constituent elements described in the first embodiment. Detailed description of these constituent elements will not be repeated.

In the fourth embodiment, a protective film 11 having weak adhesive force and a protective film 11C having strong adhesive force are bonded in an overlapping manner.

An adhesive strengthening layer 1C is formed not only in a region along a periphery of the mother glass substrate 50, but also in an entire surface of the mother glass substrate 50 to cover an adhesive layer 13 and the protective film 11 formed in a center portion. Then, the protective film 11C is formed on the adhesive strengthening layer 1C.

As a result, although the two protective films 11 and 11C are necessary and the number of necessary protective films increases, inexpensive protective films can be used for the protective films 11 and 11C, rather than special protective films as in the first embodiment. In addition, equipment for UV irradiation and the like as in the third embodiment becomes unnecessary. Therefore, in addition to the effect of the first embodiment, the total cost for a separation step can be reduced.

The EL display according to the present embodiment includes, for example, an Electro Luminescence (EL) display such as an organic EL display including an Organic Light Emitting Diode (OLED) or an inorganic EL display including an inorganic light emitting diode, and a Quantum Dot Light Emitting Diode (QLED) display including a QLED.

### Supplement

A method of producing an EL device according to a first aspect includes layering a resin layer, a barrier layer and a protective film on a mother glass substrate; irradiating with a laser beam from a side opposite to the resin layer of the mother glass substrate; separating the mother glass substrate from the resin layer by inserting a knife along an interface between the mother glass substrate and the resin layer; and bonding a lower face film to the resin layer from which the mother glass substrate is separated, and in the method, the layering includes forming, along an end face of the mother glass substrate, an adhesive strengthening layer to strengthen adhesive force between the barrier layer and the protective film.

In a second aspect, the layering includes layering a light emitting element layer between the barrier layer and the protective film, and the barrier layer is formed to cover an entire surface of the resin layer.

In a third aspect, the adhesive strengthening layer is formed along at least one side of the mother glass substrate.

In a fourth aspect, the adhesive strengthening layer is formed to reach the end face of the mother glass substrate.

In a fifth aspect, the resin layer includes an inclined surface having a film thickness decreasing toward the end face of the mother glass substrate, and the adhesive strengthening layer is formed on the inclined surface.

In a sixth aspect, an adhesive layer having adhesive force less than adhesive force of the adhesive strengthening layer is formed on an inner side and an outer side of the adhesive strengthening layer.

In a seventh aspect, the adhesive strengthening layer includes a photocurable resin or a thermosetting resin.

In an eighth aspect, the photocurable resin includes a UV-curable resin.

In a ninth aspect, the adhesive strengthening layer is formed to cover an entire surface of the mother glass substrate.

In a tenth aspect, the layering includes layering a second protective film between the barrier layer and the adhesive strengthening layer, the second protective film is formed on an inner side of an end face of the resin layer, and adhesive force between the second protective film and the barrier layer is less than adhesive force between the protective film and the barrier layer.

In an eleventh aspect, the method of producing an EL device further includes dividing the mother glass substrate to which the lower face film is bonded, to form a plurality of individual EL devices.

An EL device producing device according to a twelfth aspect includes a layering mechanism configured to layer a resin layer, a barrier layer and a protective film on a mother glass substrate; an irradiation mechanism configured to irradiate with a laser beam from a side opposite to the resin layer of the mother glass substrate; a separation mechanism configured to separate the mother glass substrate from the resin layer by inserting a knife along an interface between the mother glass substrate and the resin layer; and a bonding mechanism configured to bond a lower face film to the resin layer from which the mother glass substrate is separated, and in the EL device producing device, the layering mechanism is configured to form, along an end face of the mother glass substrate, an adhesive strengthening layer to strengthen adhesive force between the barrier layer and the protective film.

The disclosure is not limited to each of the embodiments described above, and various modifications can be implemented within the scope of the claims. Embodiments obtained by appropriately combining the technical approaches disclosed in each of the different embodiments also fall within the technical scope of the disclosure. Further, novel technical features can be formed by combining the technical approaches disclosed in each of the embodiments.

### REFERENCE SIGNS LIST

1 Adhesive strengthening layer
2 EL device
3 Barrier layer
11 Protective film
11A Second protective film
12 Resin layer
13 Adhesive layer
14 Inclined surface
28 Inorganic sealing film
50 Mother glass substrate
50A Lower face film
51 End face
61 Laser beam irradiation mechanism
62 Knife (separation mechanism)
63 Layering mechanism
64 Bonding mechanism

1. A method of producing an EL device, the method comprising:
layering a resin layer, a barrier layer and a protective film on a mother glass substrate;
irradiating with a laser beam from a side opposite to the resin layer of the mother glass substrate;
separating the mother glass substrate from the resin layer by inserting a knife along an interface between the mother glass substrate and the resin layer; and
bonding a lower face film to the resin layer from which the mother glass substrate is separated,
wherein the layering includes forming, along an end face of the mother glass substrate, an adhesive strengthening layer to strengthen adhesive force between the barrier layer and the protective film.

2. The method of producing an EL device according to claim 1,
wherein the layering includes layering a light emitting element layer between the barrier layer and the protective film, and
the barrier layer is formed to cover an entire surface of the resin layer.

3. The method of producing an EL device according to claim 1,
wherein the adhesive strengthening layer is formed along at least one side of the mother glass substrate.

4. The method of producing an EL device according to claim 1,
wherein the adhesive strengthening layer is formed to reach the end face of the mother glass substrate.

5. The method of producing an EL device according to claim 1,
wherein the resin layer includes an inclined surface having a film thickness decreasing toward the end face of the mother glass substrate, and
the adhesive strengthening layer is formed on the inclined surface.

6. The method of producing an EL device according to claim 5,
wherein an adhesive layer having adhesive force less than adhesive force of the adhesive strengthening layer is formed on an inner side and an outer side of the adhesive strengthening layer.

7. The method of producing an EL device according to claim 1,
wherein the adhesive strengthening layer includes a photocurable resin or a thermosetting resin.

8. The method of producing an EL device according to claim 7,
wherein the photocurable resin includes a UV-curable resin.

9. The method of producing an EL device according to claim 1,
wherein the adhesive strengthening layer is formed to cover an entire surface of the mother glass substrate.

10. The method of producing an EL device according to claim 9,
wherein the layering includes layering a second protective film between the barrier layer and the adhesive strengthening layer,
the second protective film is formed on an inner side of an end face of the resin layer, and
adhesive force between the second protective film and the barrier layer is less than adhesive force between the protective film and the barrier layer.

11. The method of producing an EL device according to claim 1, further comprising:
dividing the mother glass substrate to which the lower face film is bonded such that a plurality of individual EL devices are formed.

12. An EL device producing device comprising:
a layering mechanism configured to layering a resin layer, a barrier layer and a protective film on a mother glass substrate;
a laser beam irradiation mechanism configured to irradiate a laser beam from a side opposite to the resin layer of the mother glass substrate;
a separation mechanism configured to separate the mother glass substrate from the resin layer by inserting a knife along an interface between the mother glass substrate and the resin layer; and
a bonding mechanism configured to bond a lower face film to the resin layer from which the mother glass substrate is separated,
wherein the layering mechanism is configured to form, along an end face of the mother glass substrate, an adhesive strengthening layer such that adhesive force between the barrier layer and the protective film is strengthened.
